(19) United States
(12) Patent Application Publication
(10) Pub. No.: US 2005/0133241 A1
(43) Pub. Date: Jun. 23, 2005

(54) Chip orientation and attachment method

(75) Inventors: Kuan-Shou Chi, Hsinchu (TW); Tai-Chun Huang, Hsin-Chu (TW); Chih-Hsiang Yao, Taipei (TW)

Correspondence Address: TUNG & ASSOCIATES, Suite 120, 838 W. Long Lake Road, Bloomfield Hills, MI, 48302, US

(73) Assignee: Taiwan Semiconductor manufacturing Co., Ltd.

(21) Appl. No.: 10/742,240

(22) Filed: Dec. 18, 2003

(51) Int. Cl. H01L 23/02; H05K 3/30

(52) U.S. Cl. 174/52.4; 29/832; 29/834

(57) ABSTRACT

A chip orientation and attachment method is disclosed which eliminates or substantially reduces chip damage caused by thermal stress induced by application of a molding compound to the chip and substrate. The chip is attached to the substrate in such a manner that at least one of the following conditions exists: the chip diagonal and the substrate diagonal are in non-aligned relationship, and/or the chip edges are non-parallel with respect to the substrate edges, and/or the chip center is in non-overlapping relationship with respect to the substrate center. The invention includes chip package structures fabricated according to the chip orientation and attachment method.

### FIELD OF THE INVENTION

The present invention relates to methods for attaching a semiconductor die or chip to a substrate. More particularly, the present invention relates to a novel chip orientation and attachment method which reduces stress applied to the corners of a chip during bonding of the chip to a substrate.

### BACKGROUND OF THE INVENTION

A conventional method used by the semiconductor industry in the manufacturing of semiconductor integrated circuits includes the steps of fabrication, wafer sort, assembly and test, respectively. In the fabrication step, as many as several thousand dies (integrated circuits) are formed onto a semiconductor wafer. In the wafer sort step, each of the dies on the wafer is tested to determine its electrical characteristics and operability, and defective dies are distinguished from operable dies. The defective dies are often marked by an ink mark at the wafer sorting step. In the assembly step, the unmarked, operable dies are assembled into a package, and in the test step, the packaged integrated circuits are tested for operability and reliability.

After the semiconductor chips or die are fabricated on a semiconductor wafer, the die are separated from each other. This is carried out typically by cutting the die from the wafer using a diamond-blade dicing saw. The wafer is initially placed on an adhesive film provided on a rigid frame. During the cutting operation, the wafer is sprayed with deionized water to remove silicon slurry residue resulting from the cutting action. The separated die are held in place on the adhesive film. Final separation of the die is achieved using fully-automated equipment which includes alignment systems and integrated wafer cleaning.

One of the last processes in the production of semiconductor integrated circuits (IC) is multi-leveled packaging, which includes expanding the electrode pitch of the IC chips containing the circuits for subsequent levels of packaging; protecting the chip from mechanical and environmental stress; providing proper thermal paths for channeling heat dissipated by the chip; and forming electronic interconnections. The manner in which the IC chips are packaged dictates the overall cost, performance, and reliability of the packaged chips, as well as of the system in which the package is applied.

Package types for IC chips can be broadly classified into two groups: hermetic-ceramic packages and plastic packages. A chip packaged in a hermetic package is isolated from the ambient environment by a vacuum-tight enclosure. The package is typically ceramic and is utilized in high-performance applications. A chip packaged in a plastic package, on the other hand, is not completely isolated from the ambient environment because the package is composed of an epoxy-based resin. Consequently, ambient air is able to penetrate the package and adversely affect the chip over time. Recent advances in plastic packaging, however, has expanded their application and performance capability. Plastic packages are cost-effective due to the fact that the production process is typically facilitated by automated batch-handling.

Packaging of dies is begun after separation of the dies from each other in the wafer. A die attach operation is then carried out in which each functional die is individually removed from the adhesive film and attached to a leadframe or substrate. An automated die bonder uses a gripper, or collet, to grasp each die by the edges and place the die on the substrate for assembly. The die bonder distinguishes functional dies from non-functional ones based typically on the presence or absence of an ink mark on each die, with the non-functional dies having been previously marked with an ink spot in a separate die testing step.

There are three basic methods for bonding chips to a leadframe or substrate: the epoxy attach method, the eutectic method and the glass frit attach method. In the epoxy attach method, an epoxy is placed in the center of the leadframe or substrate and the back surface of the chip is placed on the epoxy. A thermal heat cycle is then used to cure the epoxy. In some applications, the epoxy is formulated with silver flakes to aid in dissipation of heat between the chip and the rest of the package.

In the eutectic method, a thin film of gold (Au) is provided on the backside of the wafer and alloyed to a metal leadframe or ceramic substrate. The substrate is heated to 420 degrees C. for approximately six seconds, during which a eutectic alloy interconnection is formed between the chip and the leadframe or substrate. The eutectic alloy interconnection enhances the thermal path and mechanical strength between a chip and a substrate or leadframe.

In the glass frit attach method, a mixture of silver and glass particles suspended in an organic medium is used to attach a chip directly to a ceramic substrate. The chip is attached to the ceramic substrate with a hermetic seal. The silver and glass in the organic medium form a bond to the substrate having good thermal conduction.

One of the most common methods of electrically connecting bond pads on a chip to inner lead terminals on a leadframe or substrate is the wirebonding method. The wirebonding method can be accomplished using high-speed operation tools, which forms a fine, typically gold or aluminum wire between the bond pads on the chip and the inner lead terminals on the substrate or leadframe. Wirebonding of a chip to a substrate is a high-speed process, with up to ten wire bonds per second capable of being formed.

After a chip is wirebonded to a leadframe or substrate, the wirebonded chip structure may undergo plastic packaging, in which an epoxy polymer is used to completely encapsulate the chip and leadframe or substrate in a molding process. Plastic packaging is amenable to high-volume production techniques. Furthermore, the plastic package facilitates flexibility in the shape of the leads, including pin-in-hole (PIH) leads, which extend through openings in the circuit board, and surface mount technology (SMT) leads, which are attached to the surface of the circuit board. SMT leads enable higher-density packaging for both the chip and the circuit board.

A typical conventional plastic chip package structure 8 is shown in FIG. 1A. The structure 8 includes a square-shaped leadframe or substrate 10 to which is attached a correspondingly square-shaped chip 12, having chip corners 14a-14d. A molding compound 16, such as an epoxy, is applied to the chip 12 and cured to encapsulate the chip 12 in a cured molding compound 18 on the substrate 10. An alternative plastic chip package 22 is shown in FIG. 1B, wherein a rectangular-shaped chip 26 having chip corners 28a-28b is bonded to a rectangular substrate 24 and is encapsulated in a cured molding compound 18, typically epoxy.

During the chip packaging process, the square chip 12 and the rectangular chip 26 are positioned in substantially the center of the correspondingly-shaped square substrate 10 and rectangular substrate 24, respectively. The molding compound 16 is applied to a corner 14a of the square chip 12 and to a corner 28a of the rectangular chip 26. This applies substantial thermal stress to the chips, causing damage to and delamination of the chip corners, particularly the corner 14c of the square chip 12 and the corner 28c of the rectangular chip 26. In the chip package structure 8 of FIG. 1A, the chip diagonal 13 of the chip 12 is aligned with the substrate diagonal 11 of the substrate 10; the chip edges 15 are parallel to the substrate edges 10a; and the center of the chip 12 overlaps the center of the substrate 10. The same conditions exist with respect to the chip package structure 22 of FIG. 1B.

It has been found that the corner-damaging and delaminating effects caused by thermal stress that is induced by molding compound application to a chip on a substrate can be substantially reduced by orientation of the chip on the substrate in such a manner that one or more of the following conditions exists: the chip diagonal and the substrate diagonal are in non-aligned relationship, the chip edges are non-parallel with respect to the substrate edges, or the chip center is in non-overlapping relationship with respect to the substrate center. Accordingly, a new and improved chip orientation and attachment method is needed for attaching a chip to a substrate in such a manner that damage to the chip induced by molding compound application is eliminated or substantially reduced.

An object of the present invention is to provide an improved chip orientation attachment method for attaching a chip to a substrate.

Another object of the present invention is to provide a new and improved chip orientation and attachment method which eliminates or substantially reduces chip damage induced by thermal stress caused by application of a molding compound to the chip.

Still another object of the present invention is to provide a new and improved chip orientation and attachment method in which at least one of the following conditions exists: the chip diagonal and the substrate diagonal are in non-aligned relationship, and/or the chip edges are non-parallel with respect to the substrate edges, and/or the chip center is in non-overlapping relationship with respect to the substrate center.

Yet another object of the present invention is to provide a new and improved chip orientation and attachment method which is applicable to attachment of a square-shaped or elongated rectangular chip on a square-shaped or elongated rectangular substrate, respectively.

A still further object of the present invention is to provide chip package structures in which a chip is attached to a substrate in such an orientation that chip damage induced by thermal stress during application of a molding compound is substantially reduced or eliminated.

### SUMMARY OF THE INVENTION

In accordance with these and other objects and advantages, the present invention is generally directed to a new and improved chip orientation and attachment method which eliminates or substantially reduces chip damage caused by thermal stress induced by application of a molding compound to the chip and substrate. The chip is attached to the substrate in such a manner that at least one of the following conditions exists: the chip diagonal and the substrate diagonal are in non-aligned relationship, and/or the chip edges are non-parallel with respect to the substrate edges, and/or the chip center is in non-overlapping relationship with respect to the substrate center.

In one embodiment, the chip is attached to the substrate in such an orientation that the chip center is non-overlapping with respect to the substrate center. In another embodiment, the chip diagonal is in non-aligned relationship with respect to the substrate diagonal and the chip edges are non-parallel with respect to the substrate edges. In still another embodiment, the chip center is non-overlapping with respect to the substrate center, the chip diagonal is in non-aligned relationship with respect to the substrate diagonal and the chip edges are non-parallel with respect to the substrate edges. In each case, the chip and substrate are typically square-shaped or elongated rectangular.

The present invention is further directed to chip package structures in which a chip is attached to a substrate in such a manner that chip damage induced by thermal stress at the molding compound-application method is eliminated, or at least, substantially reduced. In a first embodiment, a square-shaped chip is attached to a square-shaped substrate with the chip center in non-overlapping with respect to the substrate center. In a second embodiment, the chip diagonal is in non-aligned relationship with respect to the substrate diagonal and the chip edges are non-parallel with respect to the substrate edges. In a third embodiment, the chip center is non-overlapping with respect to the substrate center, the chip diagonal is in non-aligned relationship with respect to the substrate diagonal and the chip edges are non-parallel with respect to the substrate edges. In fourth, fifth and sixth embodiments, the same conditions exist with respect to the first, second and third chip package structures, respectively, except both the chip and the substrate have an elongated rectangular shape.

### BRIEF DESCRIPTION OF THE DRAWINGS

The invention will be described, by way of example, with reference to the accompanying drawings, in which:

FIG. 1A is a top, partially schematic, view of a conventional chip package structure in which a square-shaped chip is oriented on a square-shaped substrate with the chip center and the substrate center overlapping each other, the chip edges and substrate edges parallel with each other, and the chip diagonal and substrate diagonal aligned with each other;

FIG. 1B is a top, partially schematic, view of a conventional chip package structure in which an elongated rectangular chip is oriented on an elongated rectangular substrate with the chip center and the substrate center overlapping each other, the chip edges and substrate edges parallel with each other, and the chip diagonal and substrate diagonal aligned with each other;

FIG. 2A is a top, partially schematic, view of a chip package structure according to the present invention, with a square-shaped chip attached to a square-shaped substrate in such a manner that the chip center is in non-overlapping relationship with respect to the substrate center and the chip diagonal is in non-alignment with respect to the substrate diagonal;

FIG. 2B is a top, partially schematic, view of a chip package structure according to the present invention, with a square-shaped chip attached to a square-shaped substrate in such a manner that the chip edges are non-parallel with respect to the substrate edges and the chip diagonal is disposed in non-alignment with respect to the substrate diagonal;

FIG. 2C is a top, partially schematic, view of a chip package structure according to the present invention, with a square-shaped chip attached to a square-shaped substrate in such a manner that the chip center is non-overlapping with respect to the substrate center, the chip edges are non-parallel with respect to the substrate edges and the chip diagonal is disposed in non-alignment with respect to the substrate diagonal;

FIG. 3A is a top, partially schematic, view of a chip package structure according to the present invention, with an elongated rectangular chip attached to an elongated rectangular substrate in such a manner that the chip center is in non-overlapping relationship with respect to the substrate center and the chip diagonal is in non-alignment with respect to the substrate diagonal;

FIG. 3B is a top, partially schematic, view of a chip package structure according to the present invention, with an elongated rectangular chip attached to an elongated rectangular substrate in such a manner that the chip edges are non-parallel with respect to the substrate edges and the chip diagonal is disposed in non-alignment with respect to the substrate diagonal; and

FIG. 3C is a top, partially schematic, view of a chip package structure according to the present invention, with an elongated rectangular chip attached to an elongated rectangular substrate in such a manner that the chip center is non-overlapping with respect to the substrate center, the chip edges are non-parallel with respect to the substrate edges and the chip diagonal is disposed in non-alignment with respect to the substrate diagonal.

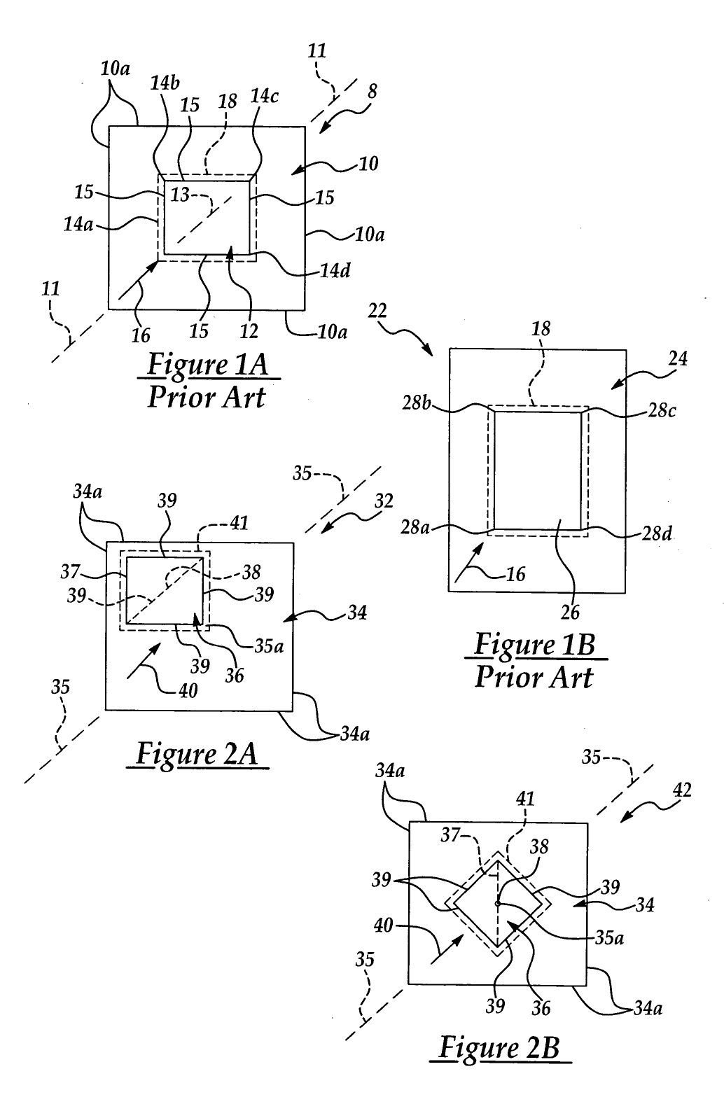

### DETAILED DESCRIPTION OF THE INVENTION

The present invention contemplates a new and improved chip orientation and attachment method which eliminates or substantially reduces chip damage caused by thermal stress induced by application of a molding compound to the chip and substrate in the plastic encapsulation packaging of the chip. The chip is initially attached to the substrate in such a manner that the chip diagonal and the substrate diagonal are in non-aligned relationship; the chip edges are non-parallel with respect to the substrate edges; or the chip center is in non-overlapping relationship with respect to the substrate center, or two or all of the above conditions exist. After the chip is attached to the substrate, the molding compound, which may be an epoxy resin, for example, is applied to the chip to encapsulate the chip on the substrate. Accordingly, the corners of the chip are positioned out of the direct flow path of the molding compound, substantially reducing thermal stress which otherwise causes damage to and delamination of a corner or corners of the chip.

The present invention further contemplates chip package structures in which a square-shaped or elongated rectangular chip is attached to a correspondingly-shaped substrate. In the respective embodiments, the chip is oriented on the substrate in such a manner that the chip diagonal and the substrate diagonal are in non-aligned relationship, and/or the chip edges are non-parallel with respect to the substrate edges, and/or the chip center is in non-overlapping relationship with respect to the substrate center. A molding compound, which may be epoxy, encapsulates the chip on the substrate.

According to the chip orientation and attachment method of the present invention, the chip may be attached to a leadframe or substrate using any of a variety of methods known by those skilled in the art. For example, the chip may be attached to the substrate using an epoxy attachment method, a eutectic attachment method or a glass frit method. Typically, the chip is wire-bonded to the substrate. The liquid molding compound is applied to the attached chip typically using equipment and methods known by those skilled in the art, to encapsulate the chip. After application, the liquid molding compound is cured, or hardened, according to thermal curing techniques and process parameters which are known by those skilled in the art.

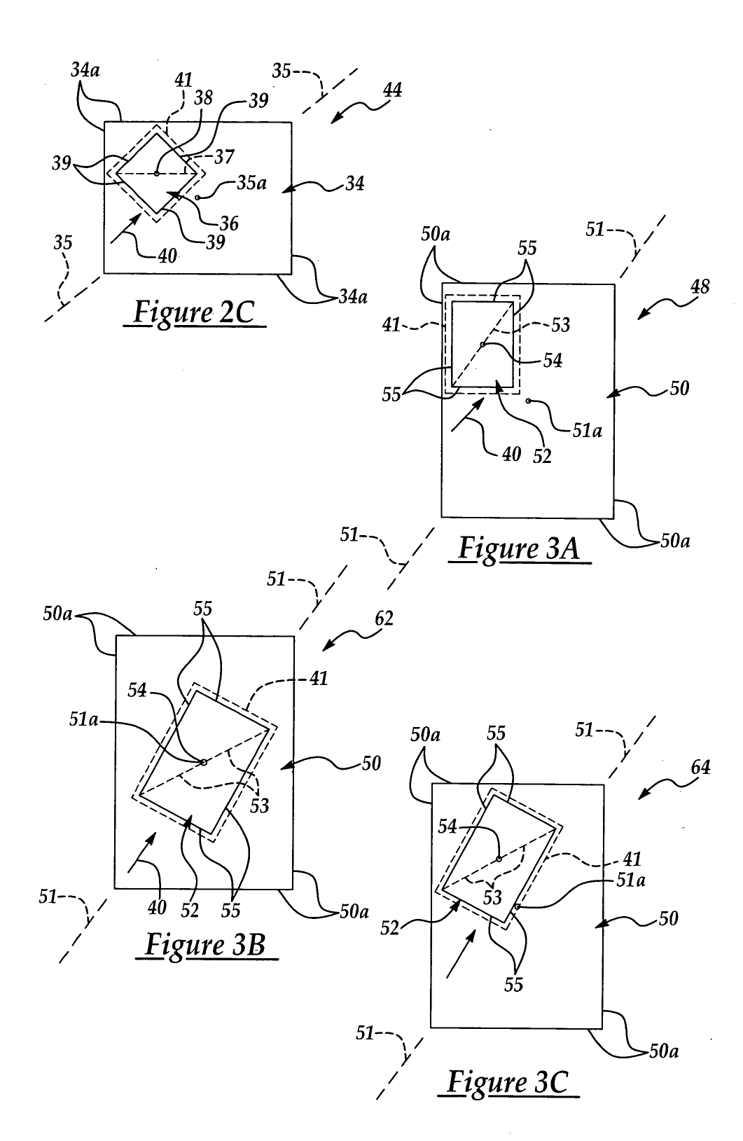

Referring to FIG. 2A, a chip package structure 32 fabricated according to a first embodiment of the chip orientation and attachment method of the present invention is shown. The chip package structure 32 includes a square-shaped chip 36 which is attached to a correspondingly square-shaped substrate 34. The chip center 38 is disposed in non-overlapping relationship to the substrate center 35a, and the chip diagonal 37 is disposed in non-aligned relationship with respect to the substrate diagonal 35. The chip edges 39, however, are disposed in substantially parallel relationship to the respective substrate edges 34a. As the liquid molding compound 40 is applied to the chip package structure 32, the compound 40 obliquely contacts an edge 39, rather than directly contacting a corner, of the chip 36. This substantially reduces the application of thermal stress to the chip 36 which would otherwise tend to damage and/or delaminate one or more corners of the chip 36. The cured molding compound 41 encapsulates the chip 36 on the substrate 34.

Referring next to FIG. 2B, a chip package structure 42 fabricated according to a second embodiment of the chip orientation and attachment method of the present invention is shown. Although the chip center 38 is disposed overlapping relationship to the substrate center 35a, the chip diagonal 37 is disposed in non-aligned relationship with respect to the substrate diagonal 35. Moreover, the chip edges 39 are disposed in non-parallel relationship to the respective substrate edges 34a. As the liquid molding compound 40 is applied to the chip package structure 32, the compound 40 directly contacts an edge 39, rather than a corner, of the chip 36 to reduce the application of thermal stress to the chip 36.

Referring next to FIG. 2C, a chip package structure 44 fabricated according to a third embodiment of the chip orientation and attachment method of the present invention is shown. The chip center 38 is disposed in non-overlapping relationship to the substrate center 35a, the chip diagonal 37 is disposed in non-aligned relationship with respect to the substrate diagonal 35 and the chip edges 39 are disposed in non-parallel relationship to the respective substrate edges 34a. The liquid molding compound 40 directly contacts an edge 39, rather than a corner, of the chip 36 to substantially reduce the application of thermal stress to the chip 36.

Referring next to FIG. 3A, a chip package structure 48 fabricated according to a fourth embodiment of the chip orientation and attachment method of the present invention is shown. The chip package structure 48 includes an elongated rectangular chip 52 which is attached to a correspondingly elongated rectangular substrate 50. The chip center 54 is disposed in non-overlapping relationship to the substrate center 51a, and the chip diagonal 53 is disposed in non-aligned relationship with respect to the substrate diagonal 51. The chip edges 55 are disposed in substantially parallel relationship to the respective substrate edges 50a. Liquid molding compound 40 applied to the chip package structure 48 obliquely contacts an edge 55, rather than directly contacting a corner, of the chip 52 to substantially reduce the application of thermal stress to the chip 52. The cured molding compound 41 encapsulates the chip 52 on the substrate 50.

Referring next to FIG. 3B, a chip package structure 62 fabricated according to a fifth embodiment of the chip orientation and attachment method of the present invention is shown. The chip center 54 is disposed overlapping relationship to the substrate center 51a. The chip diagonal 53 is disposed in non-aligned relationship with respect to the substrate diagonal 51, and the chip edges 55 are disposed in non-parallel relationship to the respective substrate edges 50a. The liquid molding compound 40 directly contacts an edge 55, rather than a corner, of the chip 36.

Referring next to FIG. 3C, in a chip package structure 64 fabricated according to a sixth embodiment of the chip orientation and attachment method of the present invention, the chip center 54 is disposed in non-overlapping relationship to the substrate center 51a, the chip diagonal 53 is disposed in non-aligned relationship with respect to the substrate diagonal 51 and the chip edges 55 are disposed in non-parallel relationship to the respective substrate edges 50a. The liquid molding compound 40 directly contacts an edge 55, rather than a corner, of the chip 52 to substantially reduce the application of thermal stress to the chip 52.

While the preferred embodiments of the invention have been described above, it will be recognized and understood that various modifications can be made in the invention and the appended claims are intended to cover all such modifications which may fall within the spirit and scope of the invention.

1. A chip orientation and attachment method, comprising the steps of:
providing a substrate having a substrate center, substrate edges and a substrate diagonal;
providing a chip having a chip center, chip edges and a chip diagonal; and
attaching said chip to said substrate wherein said chip edges and said substrate edges are generally non-parallel to each other, respectively, and said chip center and said substrate center are generally non-overlapping.

2. The method of claim 1 wherein said chip diagonal and said substrate diagonal are in generally non-aligned relationship.

3-8. (canceled)

9. A chip orientation and attachment method, comprising the steps of:
providing a generally rectangular substrate having a substrate center, substrate edges and a substrate diagonal;
providing a generally rectangular chip having a chip center, chip edges and a chip diagonal; and
attaching said chip to said substrate wherein said chip edges and said substrate edges are generally non-parallel to each other, respectively, and said chip center and said substrate center are generally non-overlapping.

10. The method of claim 9 wherein said substrate and said chip each has a generally square-shaped configuration.

11. The method of claim 9 wherein said substrate and said chip each has a generally elongated rectangular configuration.

12. The method of claim 9 wherein said chip diagonal and said substrate diagonal are in generally non-aligned relationship.

13-16. (canceled)

17. A chip package structure comprising:
a generally rectangular substrate having a substrate center, substrate edges and a substrate diagonal;
a generally rectangular chip carried by said substrate and having a chip center, chip edges and a chip diagonal;
wherein said chip edges and said substrate edges are generally non-parallel to each other, respectively, and said chip-center and said substrate center are generally non-overlapping; and
a molding compound generally encapsulating said chip.

18. The structure of claim 17 wherein said chip diagonal and said substrate diagonal are in generally non-aligned relationship.

19. The structure of claim 17 wherein each of said substrate and said chip has a generally square-shaped configuration.

20. The structure of claim 17 wherein each of said substrate and said chip has a generally elongated, rectangular configuration.
